(19) United States
(12) Patent Application Publication
(10) Pub. No.: US 2011/0061902 A1
(43) Pub. Date: Mar. 17, 2011

(54) Circuit board and method of manufacturing the same

(75) Inventors: Hee Bum Lee, Suwon (KR); Kyoung Soo Chae, Suwon (KR)

(73) Assignee: SAMSUNG ELECTRO-MECHANICS CO., LTD., Suwon (KR)

(21) Appl. No.: 12/654,674

(22) Filed: Dec. 29, 2009

(30) Foreign Application Priority Data
Sep. 11, 2009 (KR) 10-2009-0085930

(51) Int. Cl. H05K 1/00

(52) U.S. Cl. 174/252

(57) ABSTRACT

There is provided a circuit board. The circuit board according to an aspect of the invention may include: an insulating base body; a plurality of circuit patterns including a first conductive pattern and a second conductive pattern facing the first conductive pattern at a predetermined interval therebetween; a printed resistor connecting the first conductive pattern and the second conductive pattern; and a heat radiation pattern provided on the insulating base body and overlapping at least partially overlapping the printed resistor.

According to an aspect of the invention, a circuit board facilitating a design of a heating structure by forming a printed resistor on a circuit board and forming a heat radiation structure overlapping or connected to the printed resistor, and a method of manufacturing the same can be provided.

### CROSS-REFERENCE TO RELATED APPLICATIONS

This application claims the priority of Korean Patent Application No. 10-2009-0085930 filed on Sep. 11, 2009, in the Korean Intellectual Property Office, the disclosure of which is incorporated herein by reference.

### BACKGROUND OF THE INVENTION

1. Field of the Invention

The present invention relates to a circuit board and a method of manufacturing the same, and more particularly, to a circuit board facilitating a design of a heating structure by forming a printed resistor on a circuit board and a heat radiation structure overlapping or connected to the printed resistor, and a method of manufacturing the same.

2. Description of the Related Art

In order to manufacture electronic products with reduced size and increased functionality in conformity with the developments in the electronics industry, technologies in electronics industry are being developed so that resistors, capacitors and integrated circuits (ICs) are embedded into boards.

General discrete chip resistors or general discrete chip capacitors are being widely mounted on the surface of printed circuit boards. Recently, printed circuit boards embedded with passive elements, such as resistors or capacitors, has been developed.

That is, the technology for passive element embedded printed circuit boards inserts passive elements inside or outside printed circuit boards using new materials and processes to thereby replace existing chip resistors or chi capacitors.

Among the above-described passive element embedded printed circuit boards, when resistors, buried inside and outside printed circuit boards, are incorporated as a part of the printed circuit boards regardless of the sizes of the printed circuit boards, these resistors are referred to as “embedded(buried) resistors”, and circuit boards having these resistors are referred to as “embedded resistor circuit boards.”

One of the most important features of these resistor embedded circuit boards is that it is unnecessary to mount discrete chip resistors on the surface of the printed circuit boards since resistors are already provided as a part of the printed circuit boards.

However, when overvoltage is applied or a deviation occurs in an applied voltage occurs, a large amount of heat is generated to thereby deteriorate or reduce the performance of embedded resistor printed circuit boards.

### SUMMARY OF THE INVENTION

An aspect of the present invention provides a circuit board facilitating a design of a heating structure by forming a printed resistor on a circuit board and forming a heat radiation pattern overlapping or connected to the printed resistor, and a method of manufacturing the same.

According to an aspect of the present invention, there is provided a circuit board including: an insulating base body; a plurality of circuit patterns including a first conductive pattern and a second conductive pattern facing the first conductive pattern at a predetermined interval therebetween; a printed resistor connecting the first conductive pattern and the second conductive pattern; and a heat radiation pattern provided on the insulating base body and overlapping at least partially overlapping the printed resistor.

The printed resistor may be formed of conductive paste including at least one of copper, gold, silver, and copper.

The printed circuit board may be provided using inkjet printing, screen printing, gravure printing or off set printing.

The circuit board may further include a protection member covering top and side surfaces of the printed resistor.

The insulating base body may be sintered ceramic sheets.

The insulating base body may be insulating layers containing polymer.

The insulating base body may be formed of aluminum.

The printed resistor may be used as a resistor of a super capacitor.

The printed resistor may be used as a resistor of a super capacitor.

According to another aspect of the present invention, there is provided a circuit board including: an insulating base body; a plurality of circuit patterns provided on the insulating base body and including a first conductive pattern, a second conductive pattern facing the first conductive pattern at a predetermined interval therebetween, and a third conductive pattern at least partially arranged between the first conductive pattern and the second conductive pattern; a printed resistor connecting the first conductive pattern and the second conductive pattern and at least partially overlapping the third conductive pattern; a conductive via at least connected to the third conductive pattern among the plurality of circuit patterns; and a heat radiation member at least partially connected to the conductive via and provided on an outermost portion of the insulating base body.

The printed resistor may be formed of conductive paste including at least one of copper, gold, silver, and copper.

The printed resistor may be provided using inkjet printing, screen printing, gravure printing or offset printing.

The circuit board may further include a protection member covering top and side surfaces of the printed resistor.

The insulating base body may be sintered ceramic sheets.

The insulating base body may be insulating layers containing polymer.

The insulating base body may be formed of aluminum.

The printed resistor may be used as a resistor of a super capacitor.

The printed resistor may be used as a resistor of a super capacitor.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view schematically illustrating a multi-layer ceramic board according to an exemplary embodiment of the present invention;

FIG. 2 is a plan view schematically illustrating a top surface of the multi-layer ceramic board of FIG. 1;

FIG. 3 is a cross-sectional view taken along the line A-A′ of FIG. 2;

FIG. 4 is a cross-sectional view schematically illustrating a multi-layer ceramic board according to another exemplary embodiment of the present invention; and

FIG. 5 is a cross-sectional view schematically illustrating a multi-layer printed circuit board according to another exemplary embodiment of the present invention.

### DETAILED DESCRIPTION OF THE PREFERRED EMBODIMENT

Exemplary embodiments of the present invention will now be described in detail with reference to the accompanying drawings. The invention may however be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

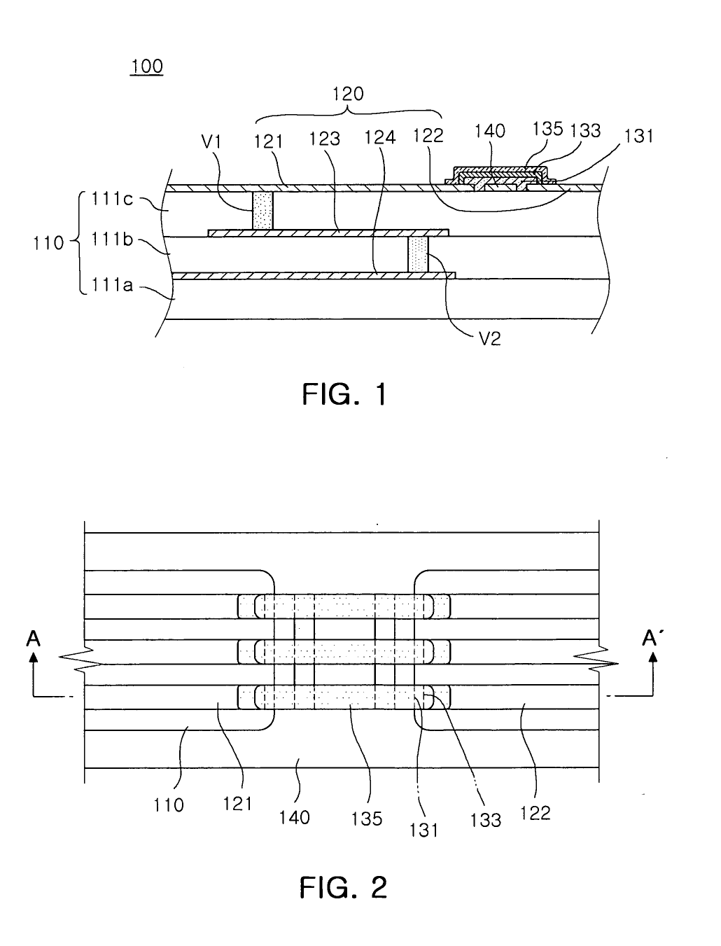

A multi-layer circuit board according to an exemplary embodiment of the invention will be described with reference to FIGS. 1 through 5.

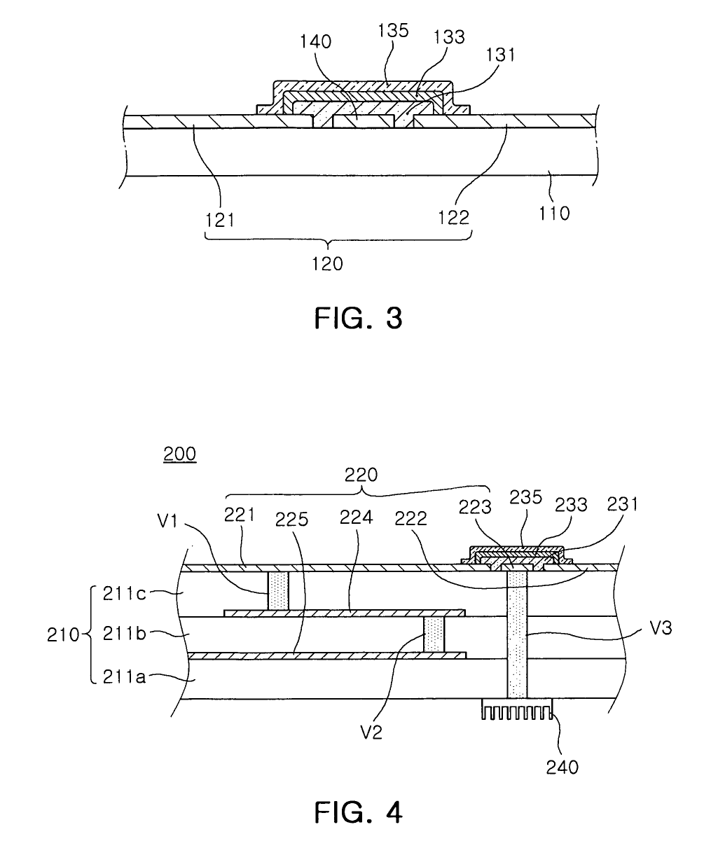

FIG. 1 is a schematic sectional view illustrating a ceramic substrate according to an exemplary embodiment of the invention. FIG. 2 is a schematic plan view illustrating a ceramic substrate according to an exemplary embodiment of the invention. FIG. 3 is a cross-sectional view taken along the line A-A′ of FIG. 2.

Referring to FIGS. 1 through 3, a ceramic substrate 100 according to an exemplary embodiment of the invention includes an insulating base body 110 having a plurality of ceramic sheets 111a, 111b, and 111c, which are insulating layers. A plurality of circuit patterns 121, 122, 123 and 124 and/or conductive vias V1 and V2 are separately formed in the first, second and third ceramic sheets 111a, 111b and 111c to thereby form a desired interlayer circuit. Here, the insulating base body 110 may be sintered ceramic sheets.

The plurality of circuit patterns 121, 122, 123 and 124 including the first conductive pattern 121 and the second conductive pattern 122 facing the first conductive pattern 121 at a predetermined interval therebetween are formed on the insulating base body 110.

A printed resistor 133 connects the first conductive pattern 121 and the second conductive pattern 122. A passivation layer 131 is formed between the printed resistor 133 and the first conductive pattern 121 and the second conductive pattern 122, so that the printed resistor 133 is insulated from the first conductive pattern 121 and the second conductive pattern 122. A protection member 135 may be further formed to cover top and side surfaces of the printed resistor 133. The protection member 135 protects the printed resistor 133 against the environment.

The printed resistor 133 may be formed of conductive paste including at least any one of carbon, gold, silver or copper. The printed resistor 133 may be forming by inkjet printing, screen printing, gravure printing or offset printing.

Referring to FIG. 3, a heat radiation pattern 140 at least partially overlapping the printed resistor 133 is formed on the insulating base body 110. The heat radiation pattern 140 is arranged in the same plane as the first conductive pattern 121 and the second conductive pattern 122 on the insulating base body 110 to thereby dissipate heat generated from the printed resistor 133.

Further, the insulating base body 110 itself may be formed of aluminum to maximize heat dissipation effects.

Hereinafter, an example in which a separate heat radiation pattern is formed on a board having the printed resistor 133 formed thereon will be described, focusing on differences from the previous embodiment.

FIG. 4 is a cross-sectional view schematically illustrating a ceramic substrate according to an exemplary embodiment of the invention.

Referring to FIG. 4, a ceramic substrate 200 according to another embodiment of the invention includes an insulating base body 210 having a plurality of ceramic sheets 211a, 211b, and 211c. A plurality of circuit patterns 221, 222, 223, 224, and 225 and/or conductive vias V1, V2, and V3 are separately formed in the plurality of first, second and third ceramic sheets 211a, 211b and 211c to thereby form a desired interlayer circuit. Here, the insulating base body 210 may be sintered ceramic sheets.

The circuit patterns 221, 222, 223, 224, and 225 including the first conductive pattern 221, the second conductive pattern 222 facing the first conductive pattern 221 at a predetermined interval therebetween, and the third conductive pattern 223 at least partially arranged between first conductive pattern 221 and the second conductive pattern 222 are formed on the insulating base body 110.

A printed resistor 233 connects the first conductive pattern 221 and the second conductive pattern 222. A passivation layer 231 is formed between the printed resistor 233 and the first conductive pattern 221 and the second conductive pattern 222, so that the printed resistor 233 is insulated from the first conductive pattern 221 and the second conductive pattern 222. The third conductive pattern 223 is formed between the first conductive pattern 221 and the second conductive pattern 222. A protection member 235 covering top and side surfaces of the printed resistor 233 may be further formed. The protection member 235 protects the printed resistor 233 against the environment.

The third conductive pattern 223 at least partially overlapping the printed resistor 233 is connected to the conductive via V3, and thus, is connected to a heat radiation member 240 provided outside the insulating base body 210. The heat radiation member 240, connected to the third conductive pattern 223, is formed on the insulating base body 210, thereby effectively dissipating heat generated from the printed resistor 233.

The printed resistor 233 may be formed of conductive paste including at least any one of carbon, gold, silver or copper. The printed resistor 233 may be forming by inkjet printing, screen printing, gravure printing or offset printing.

Hereinafter, an example in which the printed resistor 133 is formed on a printed circuit board will be described, focusing on differences from the previous embodiment.

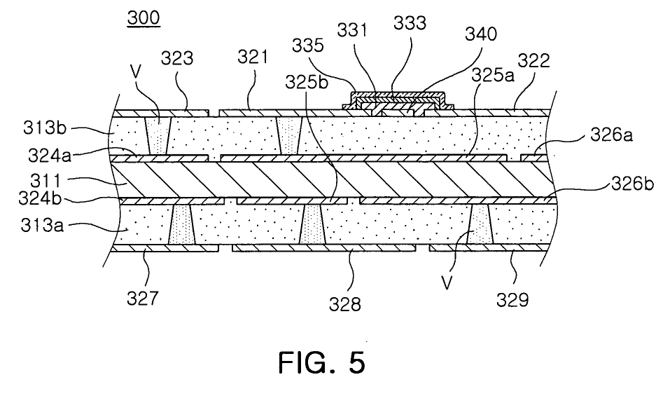

FIG. 5 is a cross-sectional view illustrating a printed circuit board according to an exemplary embodiment of the invention.

Referring to FIG. 5, a printed circuit board 300 according to another embodiment of the invention includes a core layer 311 formed of insulating polymer and first and second insulating layers 313a and 313b formed on both surfaces of the core layer 311. Conductive patterns 324a, 324b, 325a, 325b, 326a and 326b are formed on both surfaces of the core layer 311. The core layer 311 and the first and second insulating layers 313a and 313b constitute an insulating base body of the printed circuit board 300. The conductive patterns 324a, 324b, 325a, 325b, 326a and 326b of the core layer 311 may be formed by patterning copper foil (not shown) previously prepared on both surfaces of the core layer 311.

The conductive patterns 324a, 324b, 325a, 325b, 326a and 326b or conductive via holes V are separately formed in the first and second insulating layers 313a and 313b to thereby form a desired interlayer circuit.

A plurality of circuit patterns 321, 322, 323, 324, 325, 326, 327, 328, and 329 including the first conductive pattern 321 and the second conductive pattern 322 facing the first conductive pattern 321 at a predetermined interval therebetween are formed on the first and second insulating layers 313a and 313b.

A printed resistor 333 connects the first conductive pattern 321 and the second conductive pattern 322. A passivation layer 331 is formed between the printed resistor 333 and the first conductive pattern 321 and the second conductive pattern 322, so that the printed resistor 333 is insulated from the first conductive pattern 321 and the second conductive pattern 322. A protection member 335 covering top and side surfaces of the printed resistor 333 may be further formed. The protection member 335 protects the printed resistor 333 against the environment.

The printed resistor 333 may be formed of conductive paste including at least any one of carbon, gold, silver or copper. The printed resistor 333 may be forming by inkjet printing, screen printing, gravure printing or off set printing.

A heat radiation pattern 340 at least partially overlapping the printed resistor 333 is formed on the first and second insulating layers 313a and 313b. The heat radiation pattern 340 is arranged in the same plane as the first conductive pattern 321 and the second conductive pattern 322 on the first and second insulating layers 313a and 313b to thereby effectively dissipate heat generated from the printed resistor 333.

In all of the exemplary embodiments of the invention, the printed resistor may be used as a resistor of a bypass circuit or a resistor of a super capacitor. In serially connected modules of a lithium ion cell or a super capacitor, individual voltage deviations may occur during a charging operation. When charging is performed in the state, overvoltage may be applied. This may cause a reduction in the inner resistance and life spans of the super capacitor or the lithium ion cell, or may result in permanent damage. In order to prevent this damage, a cell-balancing circuit is configured. A passive circuit using a passive element or an active circuit using an active element is used. Here, a resistor is used to limit the amount of currents being bypassed, which requires a test process and an operation involving manual insertion. However, instead of performing this operation or process, by printing the printed resistor according to this embodiment of the invention onto a board, a simple test is possible during the manufacturing process. Since a bypass circuit has heat generation characteristics, a resistor with a few watts of power is used for heat dissipation in a lithium ion cell or a super capacitor having large capacitance. However, as a printed resistor is printed, it is possible to facilitate a design of a heating structure using a board or a heat radiation member on the board.

As set forth above, according to exemplary embodiments of the invention, a circuit board facilitating a design of a heating structure by forming a printed resistor on a circuit board and forming a heat radiation structure overlapping or connected to the printed resistor, and a method of manufacturing the same can be provided.

Furthermore, a resistor, which can be used as a resistor of a bypass circuit or a resistor of a super capacitor, can be formed by printing the resistor on a circuit board through a simple process, so that a heat radiation structure overlapping or connected to the printed resistor can be formed.

While the present invention has been shown and described in connection with the exemplary embodiments, it will be apparent to those skilled in the art that modifications and variations can be made without departing from the spirit and scope of the invention as defined by the appended claims.

What is claimed is:

1. A circuit board comprising:
an insulating base body;
a plurality of circuit patterns including a first conductive pattern and a second conductive pattern facing the first conductive pattern at a predetermined interval therebetween;
a printed resistor connecting the first conductive pattern and the second conductive pattern; and
a heat radiation pattern provided on the insulating base body and overlapping at least partially overlapping the printed resistor.

2. The circuit board of claim 1, wherein the printed resistor is formed of conductive paste including at least one of copper, gold, silver, and copper.

3. The circuit board of claim 1, wherein the printed circuit board is provided using inkjet printing, screen printing, gravure printing or offset printing.

4. The circuit board of claim 1, further comprising a protection member covering top and side surfaces of the printed resistor.

5. The circuit board of claim 1, wherein the insulating base body is sintered ceramic sheets.

6. The circuit board of claim 1, wherein the insulating base body is insulating layers containing polymer.

7. The circuit board of claim 1, wherein the insulating base body is formed of aluminum.

8. The circuit board of claim 1, wherein the printed resistor is used as a resistor of a super capacitor.

9. The circuit board of claim 1, wherein the printed resistor is used as a resistor of a super capacitor.

10. A circuit board comprising:
an insulating base body;
a plurality of circuit patterns provided on the insulating base body and including a first conductive pattern, a second conductive pattern facing the first conductive pattern at a predetermined interval therebetween, and a third conductive pattern at least partially arranged between the first conductive pattern and the second conductive pattern;
a printed resistor connecting the first conductive pattern and the second conductive pattern and at least partially overlapping the third conductive pattern;
a conductive via at least connected to the third conductive pattern among the plurality of circuit patterns; and
a heat radiation member at least partially connected to the conductive via and provided on an outermost portion of the insulating base body.

11. The circuit board of claim 10, wherein the printed resistor is formed of conductive paste including at least one of copper, gold, silver, and copper.

12. The circuit board of claim 10, wherein the printed resistor is provided using inkjet printing, screen printing, gravure printing or offset printing.

13. The circuit board of claim 10, further comprising a protection member covering top and side surfaces of the printed resistor.

14. The circuit board of claim 10, wherein the insulating base body is sintered ceramic sheets.

15. The circuit board of claim 10, wherein the insulating base body is insulating layers containing polymer.

16. The circuit board of claim 10, wherein the insulating base body is formed of aluminum.

17. The circuit board of claim 10, wherein the printed resistor is used as a resistor of a super capacitor.

18. The circuit board of claim 10, wherein the printed resistor is used as a resistor of a super capacitor.
